(19) United States
(12) Patent Application Publication
(10) Pub. No.: US 2024/0105611 A1
(43) Pub. Date: Mar. 28, 2024

(54) BACKSIDE SIGNAL INTEGRATION THROUGH VIA TO SIGNAL LINE CONNECTION

(71) Applicant: International Business Machines Corporation, Armonk, NY (US)

(72) Inventors: Lawrence A. Clevenger, Saratoga Springs, NY (US); Brent A. Anderson, Jericho, VT (US); Kisik Choi, Watervliet, NY (US); Ruilong Xie, Niskayuna, NY (US)

(21) Appl. No.: 17/950,293

(22) Filed: Sep. 22, 2022

(51) Int. Cl. H01L 23/528; H01L 29/417

(52) U.S. Cl. CPC H01L 23/5286; H01L 29/41725

(57) ABSTRACT

A semiconductor device includes an isolation region and at least one transistor including a gate region, wherein the gate region is disposed on the isolation region. A via is disposed through a portion of the isolation region and on a signal line. A gate contact is disposed on the gate region. The via is connected to the gate contact and the signal line is connected to the gate region through the via and the gate contact.

### BACKGROUND

The present application relates to semiconductors, and more specifically, to techniques for forming semiconductor structures. Semiconductors and integrated circuit chips have become ubiquitous within many products, particularly as they continue to decrease in cost and size. There is a continued desire to reduce the size of structural features and/or to provide a greater amount of structural features for a given chip size. Miniaturization, in general, allows for increased performance at lower power levels and lower cost. Present technology is at or approaching atomic level scaling of certain micro-devices such as logic gates, field-effect transistors (FETs), and capacitors.

### SUMMARY

Embodiments of the invention provide techniques for integrating backside signals through a gate contact and a via to signal line connection.

In one embodiment, a semiconductor device includes an isolation region and at least one transistor including a gate region, wherein the gate region is disposed on the isolation region. A via is disposed through a portion of the isolation region and on a signal line. A gate contact is disposed on the gate region. The via is connected to the gate contact and the signal line is connected to the gate region through the via and the gate contact.

In another embodiment, a semiconductor device includes an isolation region and at least one transistor including a gate region and source/drain region. A first via is disposed through a first portion of the isolation region and on a signal line, wherein the first via connects the signal line to the gate region. A second via is disposed through a second portion of the isolation region and on a power element, wherein the second via connects the power element to the source/drain region.

In another embodiment, an integrated circuit includes at least one transistor including a gate region and source/drain region. A first via is disposed on a signal line, wherein the first via connects the signal line to the gate region. A second via is disposed on a power element, wherein the second via connects the power element to the source/drain region. The signal line is disposed in a same metallization level as the power element.

These and other features and advantages of embodiments described herein will become more apparent from the accompanying drawings and the following detailed description.

### BRIEF DESCRIPTION OF THE DRAWINGS

FIG. 1A is a schematic top view of a transistor structure, according to an embodiment of the invention.

FIG. 1B is a schematic cross-sectional view taken along a first axis and illustrating the transistor structure of FIG. 1A following replacement metal gate (RMG) processing, according to an embodiment of the invention.

FIG. 1C is a schematic cross-sectional view taken along a second axis and illustrating the transistor structure of FIG. 1A following RMG processing, according to an embodiment of the invention.

FIG. 2A is a schematic cross-sectional view taken along a first axis and illustrating gate contact formation, via formation, metallization, back-end-of-line (BEOL) layer formation and carrier wafer bonding for the FIG. 1B structure, according to an embodiment of the invention.

FIG. 2B is a schematic cross-sectional view taken along a second axis and illustrating source/drain contact formation, via formation, metallization, BEOL layer formation and carrier wafer bonding for the FIG. 1C structure, according to an embodiment of the invention.

FIG. 3A is a schematic cross-sectional view taken along a first axis and illustrating rotation of and substrate removal from the FIG. 2A structure, according to an embodiment of the invention.

FIG. 3B is a schematic cross-sectional view taken along a second axis and illustrating rotation of and substrate removal from the FIG. 2B structure, according to an embodiment of the invention.

FIG. 4A is a schematic cross-sectional view taken along a first axis and illustrating etch stop layer and selective semiconductor layer removal from the FIG. 3A structure, according to an embodiment of the invention.

FIG. 4B is a schematic cross-sectional view taken along a second axis and illustrating etch stop layer and selective semiconductor layer removal from the FIG. 3B structure.

FIG. 5A is a schematic cross-sectional view taken along a first axis and illustrating backside inter-layer dielectric (ILD) deposition and metallization layer formation on the FIG. 4A structure, according to an embodiment of the invention.

FIG. 5B is a schematic cross-sectional view taken along a second axis and illustrating backside ILD deposition and metallization layer formation on the FIG. 4B structure, according to an embodiment of the invention.

FIG. 6A is a schematic cross-sectional view taken along a first axis and illustrating backside interconnect and power delivery network layer formation on the FIG. 5A structure, according to an embodiment of the invention.

FIG. 6B is a schematic cross-sectional view taken along a second axis and illustrating backside interconnect and power delivery network layer formation on the FIG. 5B structure, according to an embodiment of the invention.

FIG. 7 is a schematic top view of the FIGS. 6A and 6B structures, according to an embodiment of the invention.

FIG. 8 is a schematic top view of a modification to the FIGS. 6A and 6B structures including a modified via to signal line and gate contact configuration, according to an embodiment of the invention.

FIG. 9 is a schematic cross-sectional view taken along a first axis and illustrating gate contact formation, via formation, metallization, BEOL layer formation and carrier wafer bonding for the FIG. 8 structure, according to an embodiment of the invention.

FIG. 10A is a schematic cross-sectional view taken along a first axis and illustrating backside interconnect and power delivery network layer formation for the FIG. 8 structure, according to an embodiment of the invention.

FIG. 10B is a schematic cross-sectional view taken along a second axis and illustrating backside interconnect and power delivery network layer formation for the FIG. 8 structure, according to an embodiment of the invention.

FIG. 11 depicts a block diagram of an integrated circuit comprising one or more semiconductor devices with gate contact and via to signal line structures, according to an embodiment of the invention.

### DETAILED DESCRIPTION

Illustrative embodiments of the invention may be described herein in the context of illustrative methods for integrating backside signals through a gate contact and a via to signal line connection, where a gate region is disposed on an isolation region, and a via disposed through a portion of the isolation region and on a signal line is connected to a gate contact disposed on the gate region, along with illustrative apparatus, systems and devices formed using such methods. However, it is to be understood that embodiments of the invention are not limited to the illustrative methods, apparatus, systems and devices but instead are more broadly applicable to other suitable methods, apparatus, systems and devices.

It is to be understood that the various features shown in the accompanying drawings are schematic illustrations that are not necessarily drawn to scale. Moreover, the same or similar reference numbers may be used throughout the drawings to denote the same or similar features, elements, or structures, and thus, a detailed explanation of the same or similar features, elements, or structures will not be repeated for each of the drawings. Further, the terms “exemplary” and “illustrative” as used herein mean “serving as an example, instance, or illustration.” Any embodiment or design described herein as “exemplary” or “illustrative” is not to be construed as preferred or advantageous over other embodiments or designs.

A field-effect transistor (FET) is a transistor having a source, a gate, and a drain, and having action that depends on the flow of carriers (electrons or holes) along a channel that runs between the source and drain. Current through the channel between the source and drain may be controlled by a transverse electric field under the gate.

FETs are widely used for switching, amplification, filtering, and other tasks. FETs include metal-oxide-semiconductor (MOS) FETs (MOSFETs). Complementary MOS (CMOS) devices are widely used, where both n-type and p-type transistors (nFET and pFET) are used to fabricate logic and other circuitry. Source and drain regions of a FET are typically formed by adding dopants to target regions of a semiconductor body on either side of a channel, with the gate being formed above the channel. The gate includes a gate dielectric over the channel and a gate conductor over the gate dielectric. The gate dielectric is an insulator material that prevents large leakage current from flowing into the channel when voltage is applied to the gate conductor while allowing applied gate voltage to produce a transverse electric field in the channel.

Various techniques may be used to reduce the size of FETs. One technique is through the use of fin-shaped channels in FinFET devices. Before the advent of FinFET arrangements, CMOS devices were typically substantially planar along the surface of the semiconductor substrate, with the exception of the FET gate disposed over the top of the channel. FinFETs utilize a vertical channel structure, increasing the surface area of the channel exposed to the gate. Thus, in FinFET structures the gate can more effectively control the channel, as the gate extends over more than one side or surface of the channel. In some FinFET arrangements, the gate encloses three surfaces of the three-dimensional channel, rather than being disposed over just the top surface of a traditional planar channel.

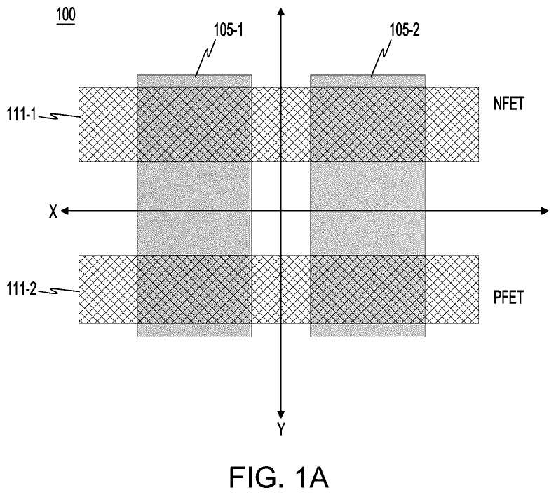

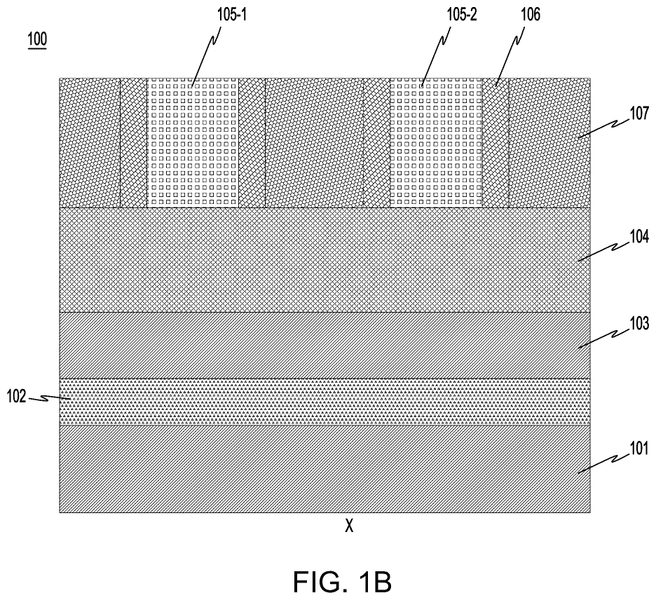

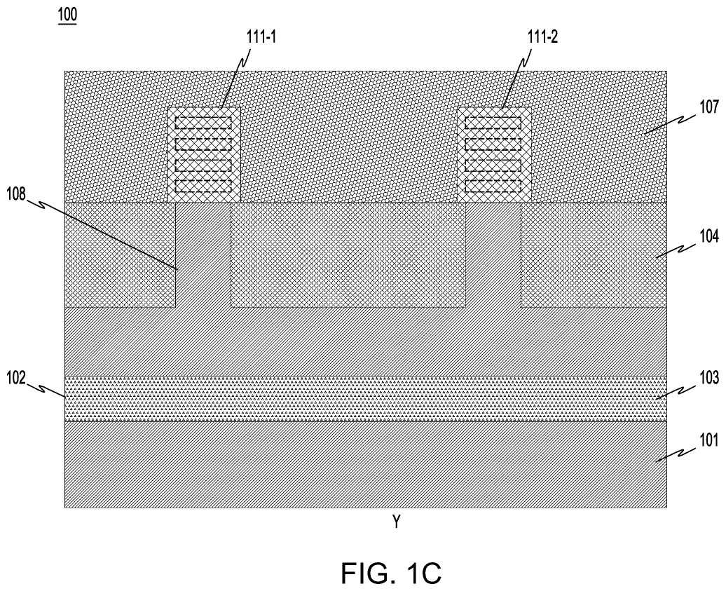

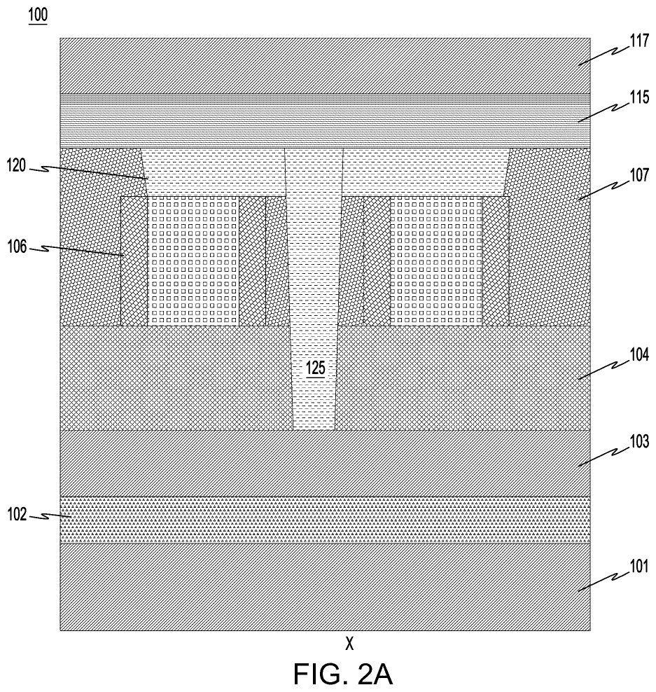

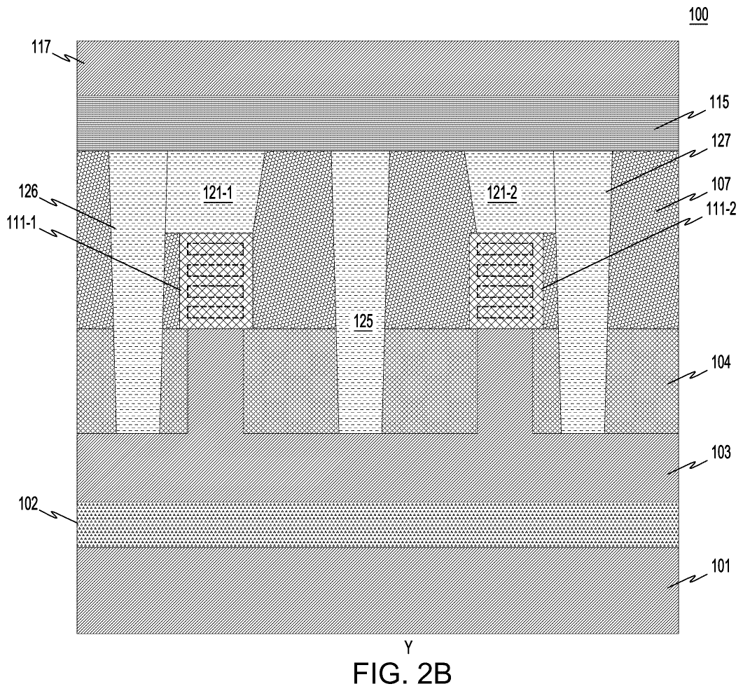

As used herein, “frontside or “first side” refers to a side on top of the semiconductor substrate 101 or semiconductor layer 103 in the orientation shown in, for example, the cross-sectional views of FIGS. 1B, 1C, 2A, 2B and 9. For example, as described in more detail herein, BEOL interconnects 115 shown in FIGS. 2A-6B and 9-10B are frontside BEOL interconnects 115.

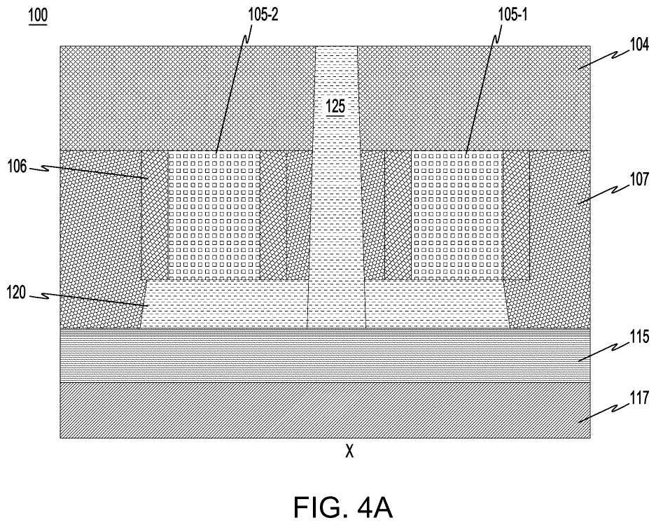

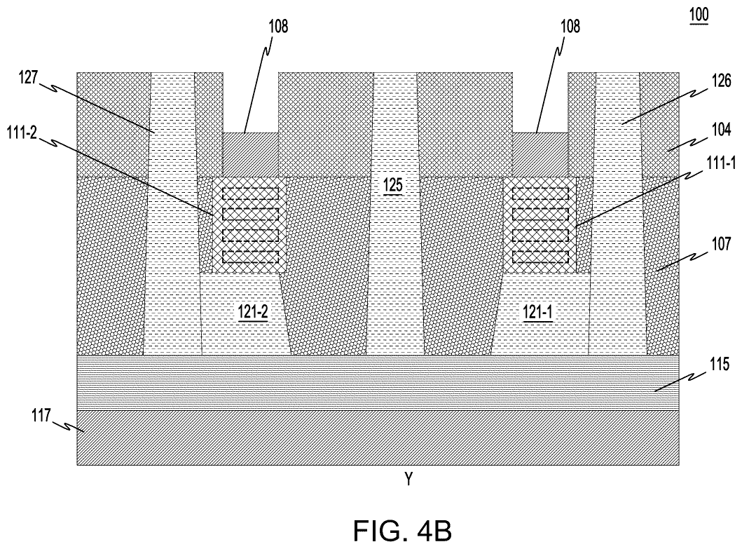

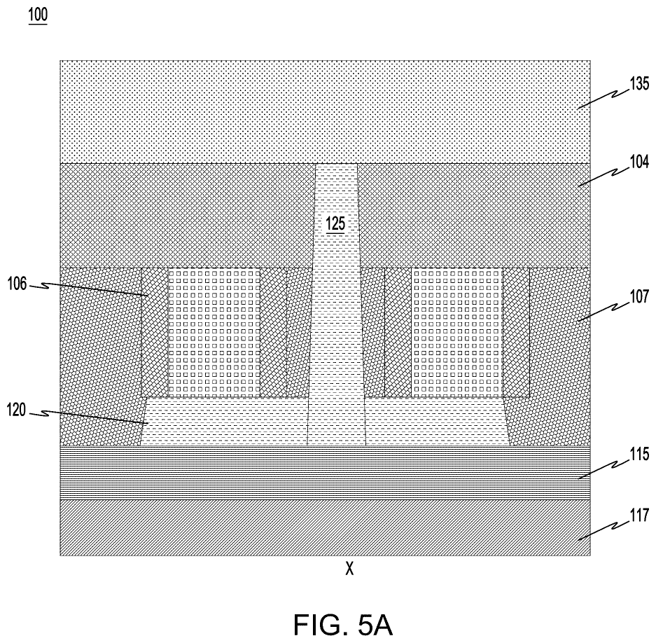

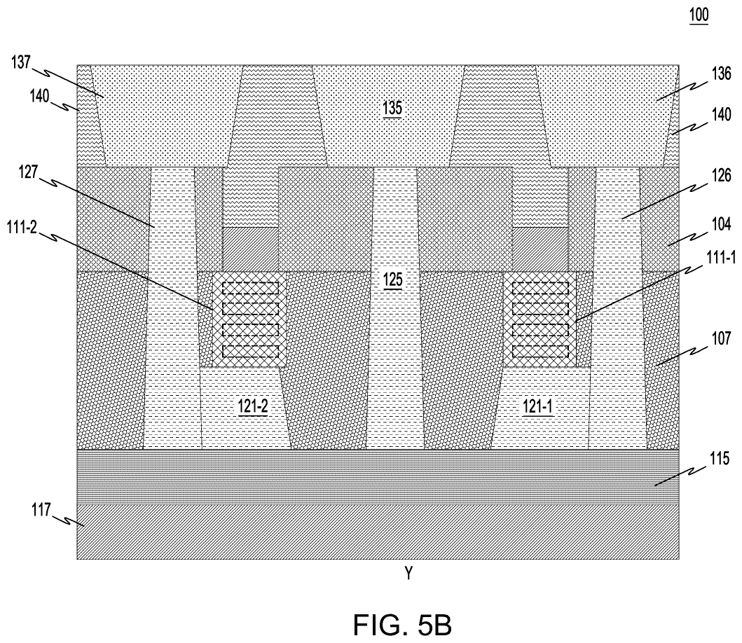

As used herein, “backside” or “second side” refers to a side on top of the dielectric layer 104 in the orientation shown in the cross-sectional views of FIGS. 4A-6B and 10A-10B (e.g., opposite the “frontside”). For example, as described in more detail herein, a signal line 135 and power rails 136 and 137 shown in FIGS. 5A-6B, 10A and 10B are a backside signal line 135 and backside power rails 136 and 137.

FIG. 1A is a schematic top view of a semiconductor device 100 having a transistor structure. FIG. 1B is a schematic cross-sectional view taken along a first axis (x-axis) and FIG. 1C is a schematic cross-sectional view taken along a second axis (y-axis). FIGS. 1B and 1C illustrate the transistor structure of FIG. 1A following RMG processing. Referring to FIGS. 1B and 1C, a semiconductor substrate 101 comprises semiconductor material including, but not limited to, silicon (Si), III-V, II-V compound semiconductor materials or other like semiconductor materials. In addition, multiple layers of the semiconductor materials can be used as the semiconductor material of the semiconductor substrate 101. An etch stop layer 102 is formed on the semiconductor substrate 101, and may comprise, for example, silicon oxide (SiOₓ) (where x is for example, 2, 1.99 or 2.01), or silicon germanium (SiGe). A semiconductor layer 103 comprising, for example, the same semiconductor material as the semiconductor substrate 101, or other like semiconductor material, is formed on the etch stop layer 102.

In accordance with an embodiment of the present invention, a dielectric layer 104 (also referred to as an isolation region or shallow trench isolation (STI) layer) is formed on the semiconductor layer 103. The dielectric layer 104 may comprise, for example, silicon nitride (SiN), silicon oxynitride (SiON), silicon-carbon-nitride (SiCN), boron nitride (BN), silicon boron nitride (SiBN), silicoboron carbonitride (SiBCN), silicon oxycarbonitride (SiOCN) and combinations thereof, and is deposited using deposition techniques such as, for example, chemical vapor deposition (CVD), plasma enhanced CVD (PECVD), radio-frequency CVD (RFCVD), physical vapor deposition (PVD), atomic layer deposition (ALD), molecular beam deposition (MBD), pulsed laser deposition (PLD), and/or liquid source misted chemical deposition (LSMCD).

The transistor structure includes a plurality of transistors (e.g., two transistors) separated from each other by portions of an inter-layer dielectric (ILD) layer 107. The ILD layer 107 may be formed of any suitable isolating material, such as SiOₓ, silicon oxycarbide (SiOC), SiOCN or some other dielectric. A first transistor comprises a gate region 105-1 and gate spacers 106 formed on sides of the gate region 105-1. A second transistor comprises a gate region 105-2 and gate spacers 106 formed on sides of the gate region 105-2. It is to be understood that the transistor structure may include more or less than two transistors.

The gate regions 105-1 and 105-2 (collectively gate regions 105) each comprise a gate conductor layer and a gate dielectric layer. The gate conductor layer may include a metal gate and/or work function metal (WFM). The WFM for the gate conductor layer may be titanium (Ti), titanium nitride (TiN), tantalum (Ta), tantalum nitride (TaN), aluminum (Al), titanium aluminum (TiAl), titanium aluminum carbon (TiAlC), a combination of Ti and Al alloys, a stack which includes a barrier layer (e.g., of TiN, TaN, etc.) followed by one or more of the aforementioned WFM materials, etc. A metal gate layer including, but not necessarily limited to, metals, such as, for example, tungsten, cobalt, zirconium, ruthenium, copper, metal carbides, metal nitrides, transition metal aluminides, tantalum carbide, titanium carbide, tantalum magnesium carbide, or combinations thereof may be deposited on the WFM layer. It should be appreciated that various other materials may be used for the gate conductor layer as desired.

A gate dielectric layer may be formed on one or more sides of the gate conductor layer and comprise a high-k dielectric material. Examples of high-k dielectric materials include, but are not limited to, metal oxides such as HfO₂ (hafnium oxide), hafnium silicon oxide (Hf—Si—O), hafnium silicon oxynitride (HfSiON), lanthanum oxide (La₂O₃), lanthanum aluminum oxide (LaAlO₃), zirconium oxide (ZrO₂), zirconium silicon oxide, zirconium silicon oxynitride, tantalum oxide (Ta₂O₅), titanium oxide (TiO₂), barium strontium titanium oxide, barium titanium oxide, strontium titanium oxide, yttrium oxide (Y₂O₃), aluminum oxide (Al₂O₃), lead scandium tantalum oxide, and lead zinc niobate. The high-k material may further include dopants such as lanthanum (La), aluminum (Al), and magnesium (Mg). The gate dielectric layer may have a uniform thickness in the range of about 1 nm to about 3 nm.

Gate spacers 106 are positioned on opposite lateral sides of the gate regions 105 of the first and second transistors. The gate spacers 106 are formed on sides of the gate regions 105, and can be formed using deposition techniques such as, for example, CVD, PECVD, RFCVD, PVD, ALD, MBD, PLD, LSMCD, etc. The gate spacers 106 are formed from material comprising for example, one or more dielectrics, including, but not necessarily limited to, SiN, silicon carbide (SiC), SiON, SiOC, SiCN, BN, SiBN, SiBCN, SiOCN, SiOₓ, and combinations thereof. The gate spacers 106 can be formed by any suitable techniques such as deposition followed by directional etching. Deposition may include but is not limited to, ALD or CVD. Directional etching may include but is not limited to, reactive ion etching (RIE).

Source/drain regions 111-1 and 111-2 (collectively source/drain regions 111) comprise epitaxial layers. The terms “epitaxial growth and/or deposition” and “epitaxially formed and/or grown,” mean the growth of a semiconductor material (crystalline material) on a deposition surface of another semiconductor material (crystalline material), in which the semiconductor material being grown (crystalline over layer) has substantially the same crystalline characteristics as the semiconductor material of the deposition surface (seed material). In an epitaxial deposition process, the chemical reactants provided by the source gases are controlled, and the system parameters are set so that the depositing atoms arrive at the deposition surface of the semiconductor substrate with sufficient energy to move about on the surface such that the depositing atoms orient themselves to the crystal arrangement of the atoms of the deposition surface. Therefore, an epitaxially grown semiconductor material has substantially the same crystalline characteristics as the deposition surface on which the epitaxially grown material is formed.

The epitaxial deposition process may employ the deposition chamber of a chemical vapor deposition type apparatus, such as a metal-organic chemical vapor deposition (MOCVD), rapid thermal chemical vapor deposition (RTCVD), ultra-high vacuum chemical vapor deposition (UHVCVD), or a low pressure chemical vapor deposition (LPCVD) apparatus. A number of different sources may be used for the epitaxial deposition of the in situ doped semiconductor material. In some embodiments, the gas source for the deposition of an epitaxially formed semiconductor material may include silicon (Si) deposited from silane, disilane, trisilane, tetrasilane, hexachlorodisilane, tetrachlorosilane, dichlorosilane, trichlorosilane, and combinations thereof. In other examples, when the semiconductor material includes germanium, a germanium gas source may be selected from the group consisting of germane, digermane, halogermane, dichlorogermane, trichlorogermane, tetrachlorogermane and combinations thereof. The temperature for epitaxial deposition typically ranges from 450° C. to 900° C. Although higher temperature typically results in faster deposition, the faster deposition may result in crystal defects and film cracking.

According to a non-limiting embodiment of the present invention, the conditions of the epitaxial growth process for the source/drain regions 111 are, for example, RTCVD epitaxial growth using SiH₄, SiH₂Cl₂, GeH₄, CH₃SiH₃, B₂H₆, PF₃, and/or H₂ gases with temperature and pressure ranges of about 450° C. to about 800° C., and about 5 Torr-about 300 Torr. Embodiments of the present invention are described in connection with source/drain regions for an n-type FET (NFET) comprising, for example, Si source/drain regions, and source/drain regions for a p-type FETs (PFET) comprising, for example, silicon germanium source/drain regions. Referring to FIG. 1A, the source/drain region 111-1 corresponds to one or more NFETs, and the source/drain region 111-2 corresponds to one or more PFETs.

The source/drain regions 111, as noted above, may be formed using epitaxial growth processes, and thus may also be referred to as epitaxial layers. The source/drain regions 111 may be suitably doped, such as by using ion implantation, gas phase doping, plasma doping, plasma immersion ion implantation, cluster doping, infusion doping, liquid phase doping, solid phase doping, etc. N-type dopants may be selected from a group of phosphorus (P), arsenic (As) and antimony (Sb), and p-type dopants may be selected from a group of boron (B), boron fluoride (BF₂), gallium (Ga), indium (In), and thallium (Tl).

In non-limiting illustrative embodiments, the source/drain regions 111 can comprise in-situ phosphorous doped (ISPD) silicon or Si:C for n-type devices, or in-situ boron doped (ISBD) silicon germanium for p-type devices, at concentrations of about 1×10¹⁹/cm³ to about 3×10²¹/cm³. By “in-situ,” it is meant that the dopant that dictates the conductivity type of the doped layer is introduced during the process step, e.g., epitaxial deposition, which forms the doped layer. The source/drain regions 111 may have a width (in horizontal direction in FIG. 1C) in the range of about 10 nm to about 30 nm.

The ILD layer 107 is formed between the source/drain regions 111, and over the top of the source/drain regions 111. Referring to FIG. 1C, the semiconductor layer 103 comprises a plurality of pedestal portions 108 on which the source/drain regions 111 are formed. A width of the pedestal portions 108 (horizontal direction in FIG. 1C) corresponds to the size of source/drain regions 111 in the same direction or a smaller width than the source/drain regions 111. Portions of the dielectric layer 104 (e.g., isolation region) fill in recessed portions of the semiconductor layer 103 between the pedestal portions 108.

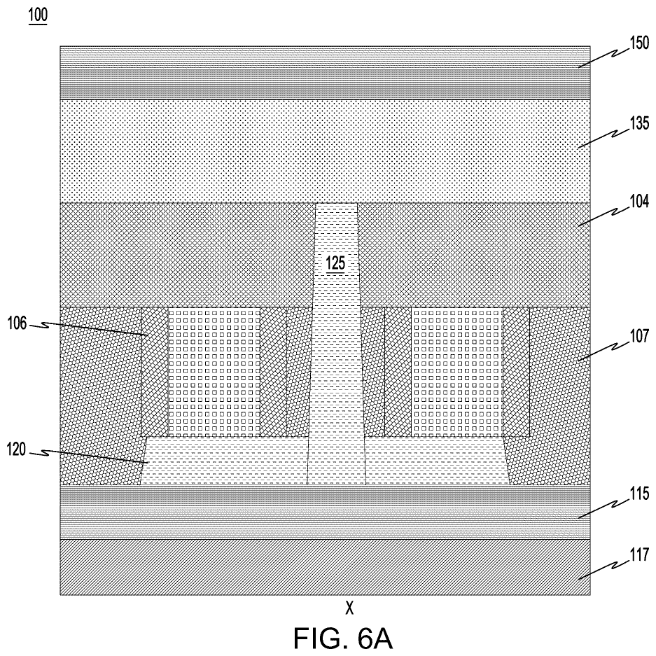

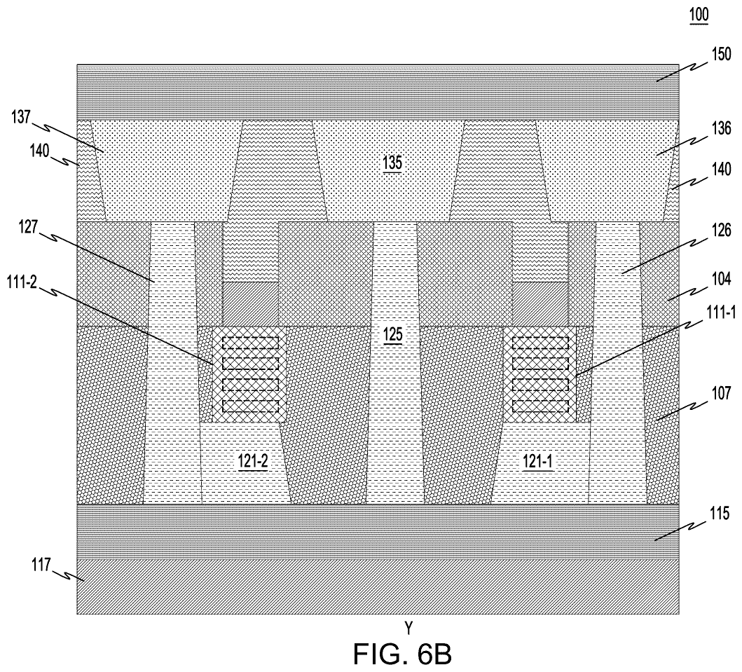

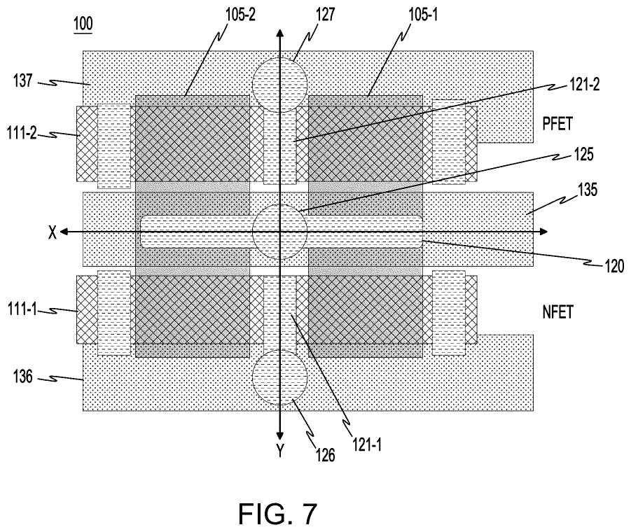

FIG. 1A depicts a simplified schematic top view of the semiconductor device 100, showing the gate regions 105 and the source/drain regions 111. The schematic cross-sectional views shown in FIGS. 1B, 2A, 3A, 4A, 5A and 6A correspond to the x-axis in FIG. 1A and/or the x-axis in FIG. 7. As explained in more detail herein, FIG. 7 is a schematic top view of the FIGS. 6A and 6B structures. The schematic cross-sectional views shown in FIGS. 1C, 2B, 3B, 4B, 5B and 6B correspond to the y-axis in FIG. 1A and/or the y-axis in FIG. 7.

Referring to FIGS. 2A and 2B, contact trenches formed through portions of the ILD layer 107 and via openings formed through portions of the ILD layer 107 and the dielectric layer 104 are filled with conductive material to form a gate contact 120, source/drain contacts 121-1 and 121-2 (collectively source/drain contacts 121) and vias 125, 126 and 127. The gate contact 120 extends on top of and between gate regions 105 and on some or all of the gate spacers 106. In the illustrative embodiment shown in FIG. 2A, the gate contact 120 is a continuous structure on both gate regions 105-1 and 105-2 and extends between the gate regions 105. The gate contact 120 lands on and contacts top surfaces of the gate regions 105 to contact at least the gate conductor layers of the gate regions 105. The source/drain contacts 121-1 and 121-2 are formed on top of and respectively contact the source/drain regions 111-1 and 111-2. As can be seen, the source/drain contacts 121-1 and 121-2 land on and contact respective source/drain regions 111-1 and 111-2.

The via 125 is formed between the gate regions 105-1 and 105-2 of two transistors. The via 125 extends from the gate contact 120 through a portion of the ILD layer 107 and an underlying portion of the dielectric layer 104 down to the semiconductor layer 103. According to an embodiment, the via 125 extends through a center or an approximate center portion of the gate contact 120. The vias 126 and 127 are formed on sides of the source/drain contacts 121-1 and 121-2 and extend through respective portions of the ILD layer 107 and underlying portions of the dielectric layer 104 down to the semiconductor layer 103. As can be seen in FIG. 2B, the via 126 contacts a left side of the source/drain contact 121-1, and the via 127 contacts a right side of the source/drain contact 121-2.

According to an embodiment, masks are formed on parts of the ILD layer 107, and exposed portions of the ILD layer 107 corresponding to where the contact trenches and via openings are to be formed are removed. In addition, underlying portions of the dielectric layer 104 corresponding to where the via openings are to be formed are also removed. The portions of the ILD layer 107 and the dielectric layer 104 can be removed using, for example, a dry etching process using a RIE or ion beam etch (IBE) process, a wet chemical etch process or a combination of these etching processes. A dry etch may be performed using a plasma. Such wet or dry etch processes include, for example, IBE by Ar/CHF3 based chemistry.

The conductive material deposited in the via openings and contact trenches to form the vias 125, 126 and 127, the gate contact 120 and the source/drain contacts 121 comprises, for example, a conductor such as, but not necessarily limited to, copper, tungsten, cobalt, ruthenium, etc., and can be deposited using, for example, a deposition technique such as CVD, PECVD, RFCVD, PVD, ALD, MBD, PLD, LSMCD, sputtering and/or plating, followed by a planarization process such as, chemical mechanical planarization (CMP) which planarizes the top surface of the semiconductor device 100, and removes excess portions of the conductive material from on top of the ILD layer 107.

Referring further to FIGS. 2A and 2B, frontside BEOL interconnects 115 are formed on the ILD layer 107 and a carrier wafer 117 is bonded to the top portion of the frontside BEOL interconnects 115. Frontside BEOL interconnects 115 are formed on the ILD layer 107 including MOL metallization layers, the vias 125, 126 and 127, the gate contact 120, and the source/drain contacts 121-1 and 121-2. The carrier wafer 117 is bonded to the frontside BEOL interconnects 115. The frontside BEOL interconnects 115 include various BEOL interconnect structures. The carrier wafer 117 may be formed of materials similar to that of the semiconductor substrate 101 and may be formed over the frontside BEOL interconnects 115 using a wafer bonding process, such as dielectric-to-dielectric bonding.

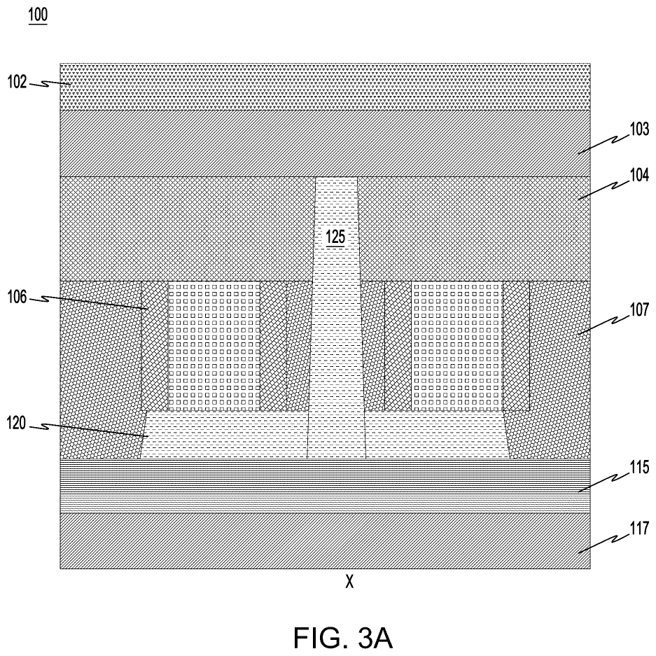

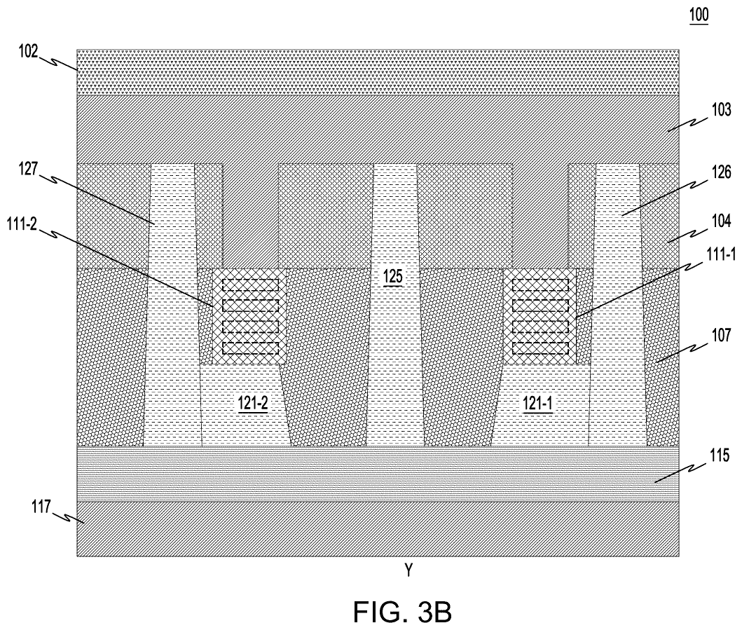

FIGS. 3A and 3B are schematic cross-sectional views illustrating rotation of and substrate removal from the FIG. 2A and FIG. 2B structures. Using the carrier wafer 117, the FIG. 2A and FIG. 2B structures may be “flipped” (e.g., rotated 180 degrees) so that the structures are inverted. In addition, the semiconductor substrate 101 is removed from the backside. The removal process, which comprises etching of the semiconductor substrate 101, stops at the etch stop layer 102 as illustrated in FIGS. 3A and 3B. For example, the semiconductor substrate 101 is selectively etched with an etchant that selectively etches silicon with respect to a material of the etch stop layer 102 (e.g., SiO₂ or SiGe).

FIGS. 4A and 4B are schematic cross-sectional views illustrating removal of the etch stop layer 102 and selective removal of the semiconductor layer 103 from the FIG. 3A and FIG. 3B structures. As shown in FIGS. 4A and 4B, the etch stop layer 102 is removed, followed by removal of the semiconductor layer 103 to expose portions of the dielectric layer 104 and the vias 125, 126 and 127. Etching of the semiconductor layer 103 is ceased at a certain point so that part of the pedestal portions 108 remain on top of the source/drain regions 111. As can be seen, the remaining parts of the pedestal portions 108 are recessed to a height that is below the exposed surfaces of the dielectric layer 104 and the vias 125, 126 and 127. Etching processes for removal of the etch stop layer 102 include, for example, IBE by Ar/CHF3 based chemistry, and etching processes for removal of the semiconductor layer 103 include, for example, IBE by Ar with SF₆ or Cl₂.

FIGS. 5A and 5B are schematic cross-sectional views illustrating deposition of a backside ILD layer 140 and formation of a backside signal line 135 and backside power rails 136 and 137 on the FIGS. 4A and 4B structures. The backside power rails 136 and 137 are also referred to as a power elements. The backside signal line 135 comprises, for example, a clock signal line. In an illustrative embodiment, the backside power rails 136 and 137 are disposed on a same metallization level as the backside signal line 135.

The backside ILD layer 140 may comprise the same or similar material to that of the ILD layer 107, and is deposited using one or more deposition techniques used for depositing the ILD layer 107. The backside ILD layer 140 fills in areas on top of the recessed pedestal portions 108 between parts of the dielectric layer 104. The backside signal line 135 and backside power rails 136 and 137 are formed in the backside ILD layer 140 by forming trenches in the backside ILD layer 140 and filling the trenches with conductive material. Trenches are respectively opened in the backside ILD layer 140 using, for example, lithography followed by RIE. The backside signal line 135 and backside power rails 136 and 137 are formed in the trenches by filling the trenches with conductive material, such as, for example, electrically conductive material including, but not necessarily limited to, tungsten, cobalt, zirconium, tantalum, titanium, aluminum, ruthenium, and/or copper. A liner layer (not shown) including, for example, titanium and/or titanium nitride, may be formed on side and bottom surfaces of the trenches before filling the trenches with the conductive material. Deposition of the conductive material can be performed using one or more deposition techniques, including, but not necessarily limited to, CVD, PECVD, PVD, ALD, MBD, PLD, LSMCD, and/or spin-on coating, followed by planarization using a planarization process, such as, for example, CMP.

The backside signal line 135 delivers, for example, clock signals from a backside clock signal line to the gate regions 105 through the via 125 and the gate contacts 120. The backside power rail 136 delivers, for example, drain voltage (VDD) through the via 126 and source/drain contact 121-1 to the corresponding source/drain region 111-1. The backside power rail 137 delivers, for example, source voltage (VSS) through via 127 to source/drain contact 121-2 to the corresponding source/drain region 111-2.

FIGS. 6A and 6B are schematic cross-sectional views illustrating formation of backside interconnect and backside power delivery network (BSPDN) layers 150 on the FIGS. 5A and 5B structures. The backside interconnect and backside power delivery network layers 150 include various BSPDN structures such as, but not necessarily limited to, interconnects in a power supply path from voltage regulator modules (VRMs) to circuits. The interconnects can comprise, for example, power and ground planes in circuit boards, cables, connectors and capacitors associated with a power supply. Backside power delivery prevents BEOL routing congestion, resulting in power performance benefits. In addition, as noted above, the backside signal line may be part of the backside interconnect and backside power delivery network layers 150 since the backside power rail is disposed on a same metallization level as the backside signal line.

As noted above, FIG. 7 is a schematic top view of the FIGS. 6A and 6B structures illustrating the backside signal line 135 and backside power rails 136 and 137, corresponding vias 125, 126 and 127, gate contact 120 and source/drain contacts 121. In addition, FIG. 7 illustrates gate regions 105 and source/drain regions 111. FIG. 7 illustrates different locations of the gate regions 105-1 and 105-2 and source/drain regions 111-1 and 111-2 from what is shown in FIG. 1A due to FIG. 7 being a top view of the flipped configuration (rotated 180 degrees) of what is depicted in the top view of FIG. 1A.

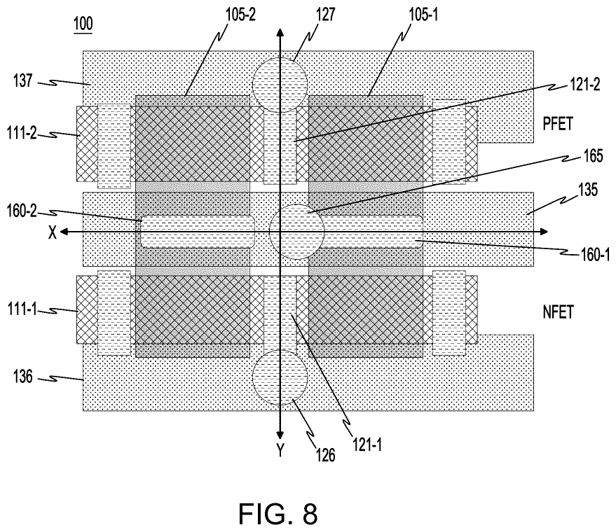

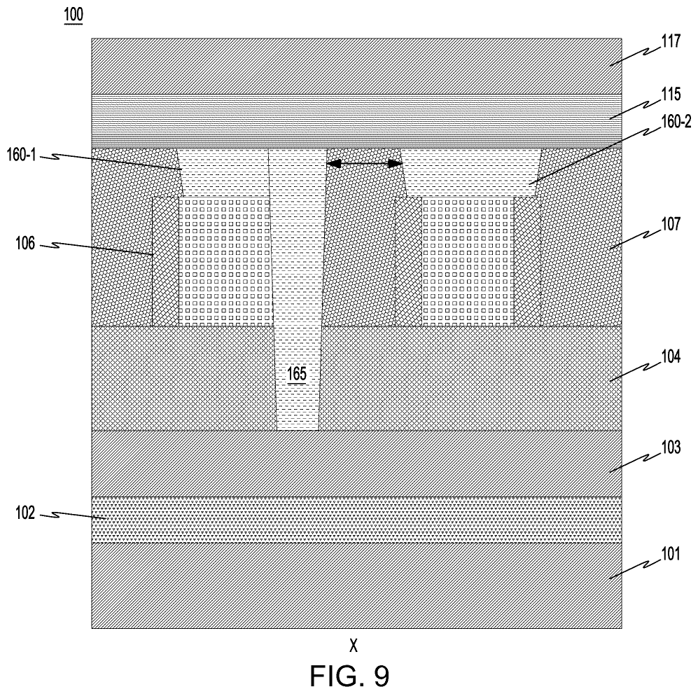

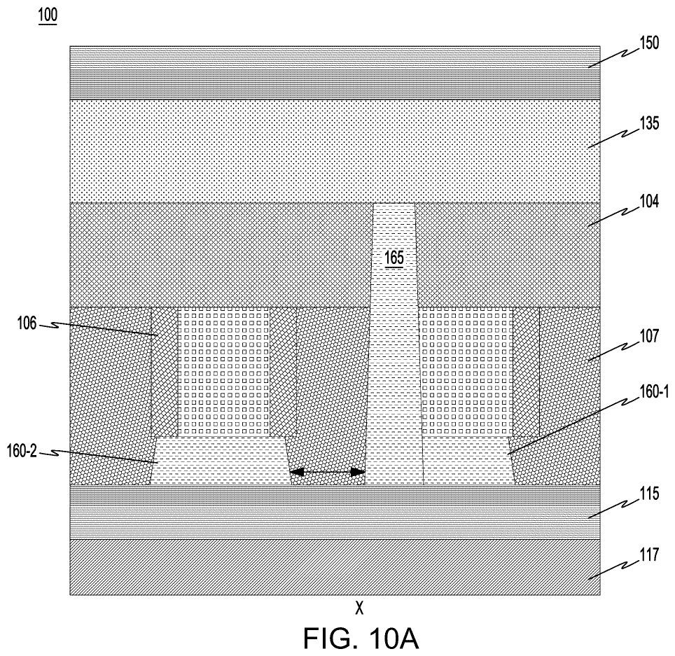

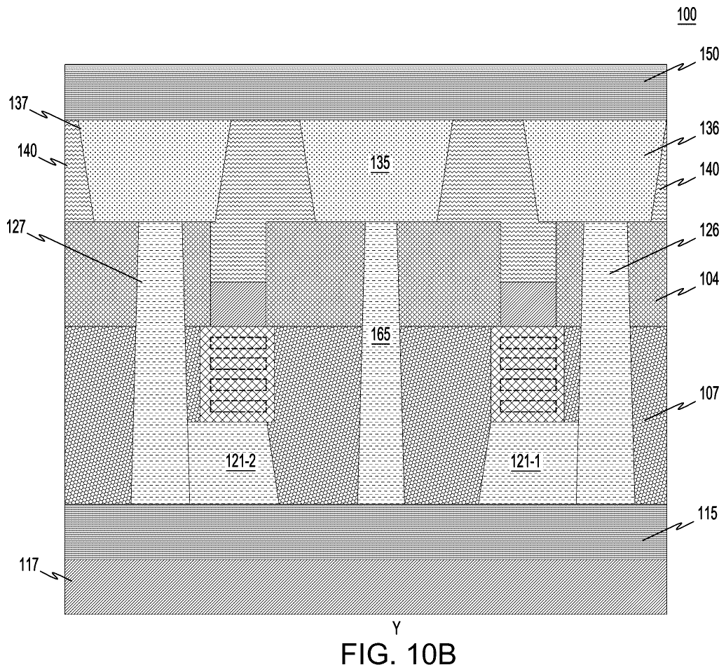

FIG. 8 is a schematic top view illustrating a modification to the FIGS. 6A, 6B and 7 structures, including a modified via to signal line and gate contact configuration. Referring to FIG. 8, the location of the signal line via (e.g., via 125, referred to as via 165 in FIG. 8) is modified, and the gate contact 120 is replaced with gate contacts 160-1 and 160-2. In more detail, instead of gate contact 120 and via 125, FIG. 8 includes via 165 and gate contacts 160-1 and 160-2. For example, FIG. 9 shows a similar structure to that shown in FIG. 2A, with via 125 replaced by via 165 and gate contact 120 replaced by gate contacts 160-1 and 160-1. The via 165 is shifted to the left relative to via 125 to contact a right side of the gate region 105-1, and a right side of gate contact 160-1. Similar to the structure in FIG. 2A, contact trenches formed through portions of the ILD layer 107 and a via opening formed through portions of the ILD layer 107 and the dielectric layer 104 are filled with conductive material to form gate contacts 160-1 and 160-2 (collectively gate contacts 160) and via 165. The gate contacts 160-1 and 160-2 are respectively formed on top of gate regions 105-1 and 105-2 and on some or all the gate spacers 106. In the illustrative embodiment shown in FIG. 9, the gate contacts 160 are separate structures on the respective gate regions 105-1 and 105-2. The gate contacts 160-1 and 160-2 land on and contact top surfaces of the respective gate regions 105-1 and 105-2 to contact at least the gate conductor layers of the gate regions 105. The schematic cross-sectional views shown in FIGS. 9 and 10A correspond to the x-axis in FIG. 8 and the schematic cross-sectional view shown in FIG. 10B corresponds to the y-axis in FIG. 8.

The via 165 is formed between the gate regions 105-1 and 105-2 of two transistors and contacts a side portion of one of the gate regions 105-1. The via 165 also contacts the side portion of gate contact 160-1 and extends through a portion of the ILD layer 107 and an underlying portion of the dielectric layer 104 down to the semiconductor layer 103.

In connection with the formation of the via 165 and the gate contacts 160-1 and 160-2, according to an embodiment, masks are formed on parts of the ILD layer 107, and exposed portions of the ILD layer 107 corresponding to where the contact trenches and via opening are to be formed are removed. In addition, a portion of the gate spacer 106 adjacent the gate region 105-1 and an underlying portion of the dielectric layer 104 corresponding to where the via opening for via 165 is to be formed are also removed. The portions of the ILD layer 107, gate spacer 106 and the dielectric layer 104 can be removed using, for example, the same or similar etching processes to those described in connection with FIG. 2B.

The conductive material deposited in the via opening and contact trenches to form the via 165 and the gate contacts 160 comprises the same or similar materials to those used for the via 125 and the gate contact 120 and is deposited by the same or similar deposition techniques, followed by a planarization process. Other processing to form additional vias and contacts is the same as that described in connection with FIGS. 2A and 2B. With reference to the arrow in FIG. 9, the distance between the via 165 and the gate contact 160-2 by locating the via 165 closer to the gate region 105-1 than gate region 105-2 avoids shorting between the via 165 and the gate contact 160-2. As can be understood, the gate contact 160-2 may have different electrical connections to the frontside BEOL interconnects 115 than those of the gate contact 160-1.

FIGS. 10A and 10B are schematic cross-sectional views illustrating formation of backside interconnect and backside power delivery network layers 150 for the FIG. 8 structure. Similar to that described in connection with FIGS. 6A and 6B, the backside interconnect and backside power delivery network layers 150 include various BSPDN structures. In addition, as noted above, the backside signal line may be part of the backside interconnect and backside power delivery network layers 150 since, in illustrative embodiments, the backside power rail is disposed on a same metallization level as the backside signal line.

Semiconductor devices and methods for forming the same in accordance with the above-described techniques can be employed in various applications, hardware, and/or electronic systems. Suitable hardware and systems for implementing embodiments of the invention may include, but are not limited to, personal computers, communication networks, electronic commerce systems, portable communications devices (e.g., cell and smart phones), solid-state media storage devices, functional circuitry, etc. Systems and hardware incorporating the semiconductor devices are contemplated embodiments of the invention. Given the teachings provided herein, one of ordinary skill in the art will be able to contemplate other implementations and applications of embodiments of the invention.

In some embodiments, the above-described techniques are used in connection with semiconductor devices that may require or otherwise utilize, for example, CMOSs, MOSFETs, and/or FinFETs. By way of non-limiting example, the semiconductor devices can include, but are not limited to CMOS, MOSFET, and FinFET devices, and/or semiconductor devices that use CMOS, MOSFET, and/or FinFET technology.

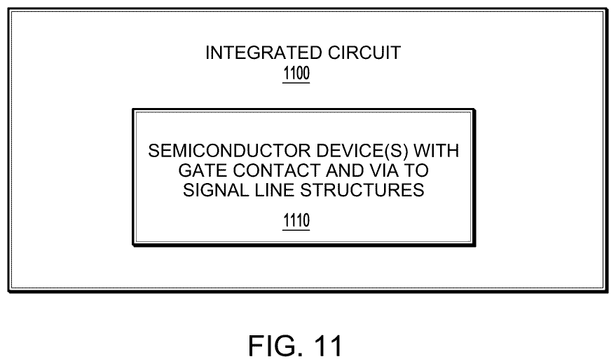

Various structures described above may be implemented in integrated circuits. The resulting integrated circuit chips can be distributed by the fabricator in raw wafer form (that is, as a single wafer that has multiple unpackaged chips), as a bare die, or in a packaged form. In the latter case the chip is mounted in a single chip package (such as a plastic carrier, with leads that are affixed to a motherboard or other higher level carrier) or in a multichip package (such as a ceramic carrier that has either or both surface interconnections or buried interconnections). In any case the chip is then integrated with other chips, discrete circuit elements, and/or other signal processing devices as part of either: (a) an intermediate product, such as a motherboard, or (b) an end product. The end product can be any product that includes integrated circuit chips, ranging from toys and other low-end applications to advanced computer products having a display, a keyboard or other input device, and a central processor. FIG. 11 shows an example integrated circuit 1100 which includes one or more semiconductor devices 1110 with the above-described via to signal line structures.

As noted above, illustrative embodiments correspond to methods for forming via to backside signal line structures for transistor devices, where a gate region is formed over an STI region, a signal line via is formed next to the gate region through the STI region, a gate contact connects the signal line via to the gate region, and a backside signal line connects to the signal line via. Advantageously, unlike conventional structures, in accordance with one or more embodiments, a backside power rail is located at the same backside metallization level as the backside signal line. Additionally, the backside power rail is connected to source/drain epitaxial regions through additional vias and source/drain contacts.

In some embodiments, the signal line via contacts a sidewall of a gate region and a corresponding gate contact, and is sufficiently separated from another adjacent gate region and gate contact to prevent shorts or other device failures between transistors while maintaining the same or smaller footprints.

It should be understood that the various layers, structures, and regions shown in the figures are schematic illustrations that are not drawn to scale. In addition, for ease of explanation, one or more layers, structures, and regions of a type commonly used to form semiconductor devices or structures may not be explicitly shown in a given figure. This does not imply that any layers, structures, and regions not explicitly shown are omitted from the actual semiconductor structures. Furthermore, it is to be understood that the embodiments discussed herein are not limited to the particular materials, features, and processing steps shown and described herein. In particular, with respect to semiconductor processing steps, it is to be emphasized that the descriptions provided herein are not intended to encompass all of the processing steps that may be required to form a functional semiconductor integrated circuit device. Rather, certain processing steps that are commonly used in forming semiconductor devices, such as, for example, wet cleaning and annealing steps, are purposefully not described herein for economy of description.

Moreover, the same or similar reference numbers are used throughout the figures to denote the same or similar features, elements, or structures, and thus, a detailed explanation of the same or similar features, elements, or structures are not repeated for each of the figures. It is to be understood that the terms “approximately” or “substantially” as used herein with regard to thicknesses, widths, percentages, ranges, temperatures, times and other process parameters, etc., are meant to denote being close or approximate to, but not exactly. For example, the term “approximately” or “substantially” as used herein implies that a small margin of error is present, such as ±5%, preferably less than 2% or 1% or less than the stated amount.

In the description above, various materials, dimensions and processing parameters for different elements are provided. Unless otherwise noted, such materials are given by way of example only and embodiments are not limited solely to the specific examples given. Similarly, unless otherwise noted, all dimensions and process parameters are given by way of example and embodiments are not limited solely to the specific dimensions or ranges given.

The descriptions of the various embodiments of the present invention have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

What is claimed is:

1. A semiconductor device, comprising:
an isolation region;
at least one transistor comprising a gate region, wherein the gate region is disposed on the isolation region;
a via disposed through a portion of the isolation region and on a signal line; and
a gate contact disposed on the gate region, wherein the via is connected to the gate contact and the signal line is connected to the gate region through the via and the gate contact.

2. The semiconductor device of claim 1, wherein the signal line is disposed in a same metallization level as a power element.

3. The semiconductor device of claim 2, wherein the power element comprises a power rail.

4. The semiconductor device of claim 2, wherein the at least one transistor further comprises a source/drain region, and the semiconductor device further comprises an additional via disposed through another portion of the isolation region and on the power element.

5. The semiconductor device of claim 4, further comprising a source/drain contact disposed on the source/drain region, wherein the additional via is connected to the source/drain contact.

6. The semiconductor device of claim 1, wherein the via contacts a side surface of the gate region.

7. The semiconductor device of claim 1, wherein the signal line comprises a clock signal line.

8. The semiconductor device of claim 1, wherein the via is disposed adjacent the gate region.

9. The semiconductor device of claim 1, further comprising at least one additional transistor comprising an additional gate region, wherein the additional gate region is disposed on the isolation region, and wherein the via is disposed between the gate region and the additional gate region.

10. The semiconductor device of claim 9, wherein the gate contact is further disposed on the additional gate region, and wherein the signal line is connected to the additional gate region through the via and the gate contact.

11. A semiconductor device, comprising:
an isolation region;
at least one transistor comprising a gate region and source/drain region;
a first via disposed through a first portion of the isolation region and on a signal line, wherein the first via connects the signal line to the gate region; and
a second via disposed through a second portion of the isolation region and on a power element, wherein the second via connects the power element to the source/drain region.

12. The semiconductor device of claim 11, wherein the signal line is disposed in a same metallization level as the power element.

13. The semiconductor device of claim 11, wherein the power element comprises a power rail.

14. The semiconductor device of claim 11, further comprising a gate contact on the gate region, wherein the first via is connected to the gate contact and the signal line is connected to the gate region through the first via and the gate contact.

15. The semiconductor device of claim 11, wherein the first via contacts a side surface of the gate region.

16. The semiconductor device of claim 11, further comprising a source/drain contact on the source/drain region, wherein the second via is connected to the source/drain contact and the power element is connected to the source/drain region through the second via and the source/drain contact.

17. An integrated circuit, comprising:
at least one transistor comprising a gate region and source/drain region;
a first via on a signal line, wherein the first via connects the signal line to the gate region; and
a second via on a power element, wherein the second via connects the power element to the source/drain region;
wherein the signal line is disposed in a same metallization level as the power element.

18. The integrated circuit of claim 17, further comprising a gate contact on the gate region, wherein the first via is connected to the gate contact and the signal line is connected to the gate region through the first via and the gate contact.

19. The integrated circuit of claim 17, wherein the first via contacts a side surface of the gate region.

20. The integrated circuit of claim 17, further comprising a source/drain contact on the source/drain region, wherein the second via is connected to the source/drain contact and the power element is connected to the source/drain region through the second via and the source/drain contact.
